(19) United States
(12) Patent Application Publication
(10) Pub. No.: US 2014/0234550 A1
(43) Pub. Date: Aug. 21, 2014

(54) ATOMIC LAYER DEPOSITION OF TRANSITION METAL THIN FILMS

(71) Applicants: Charles H. Winter, Bloomfield Hills, MI (US); Thomas J. Knisley, Monroe, MI (US); Thiloka Ariyasena, Detroit, MI (US)

(72) Inventors: Charles H. Winter, Bloomfield Hills, MI (US); Thomas J. Knisley, Monroe, MI (US); Thiloka Ariyasena, Detroit, MI (US)

(73) Assignee: WAYNE STATE UNIVERSITY, Detroit, MI (US)

(21) Appl. No.: 14/130,987

(22) PCT Filed: Jun. 5, 2012
(86) PCT No.: PCT/US2012/040892

§ 371 Date: Apr. 14, 2014

Related U.S. Application Data
(60) Provisional application No. 61/504,859, filed on Jul. 6, 2011.

(51) Int. Cl. C23C 16/18

(52) U.S. Cl. CPC C23C 16/18
USPC 427/535; 427/117

(57) ABSTRACT

An atomic layer deposition method for forming metal films on a substrate comprises a deposition cycle including:
a) contacting a substrate with a vapor of a metal-containing compound described by formula 1 for a first predetermined pulse time to form a first modified surface:

MLₙ (1)

wherein:
n is 1 to 8;
M is a transition metal;
L is a ligand;
b) contacting the first modified surface with an acid for a second predetermined pulse time to form a second modified surface; and
c) contacting the second modified surface with a reducing agent for a third predetermined pulse time to form a metal layer.

### CROSS-REFERENCE TO RELATED APPLICATIONS

The present application claims the benefit of U.S. Provisional Application No. 61/504,859 filed Jul. 6, 2011.

### FIELD OF THE INVENTION

In at least one aspect, the present invention relates to methods for forming metal layers by atomic layer deposition at low temperatures.

### BACKGROUND OF THE INVENTION

There are currently few atomic layer deposition thin film growth processes for transition metal thin films, especially for copper, nickel, cobalt, and manganese. Copper is used as the wiring material in microelectronic devices. To meet the coating requirements of future microelectronic devices, atomic layer deposition must be used as the film growth technique. In addition, the growth temperatures must be as low as possible (e.g., 100° C.).

Accordingly, there is a need for improved processes for depositing thin metal films by atomic layer deposition.

### SUMMARY OF THE INVENTION

The present invention solves one or more problems of the prior art by providing in at least one embodiment an atomic layer deposition (ALD) method for forming metal films on a substrate. The method comprises a deposition cycle including:

a) contacting a substrate with a vapor of a metal-containing compound described by formula 1 for a first predetermined pulse time to form a first modified surface:

MLₙ (1)

n is 1 to 8;
M is a transition metal;
L is a ligand;

b) contacting the first modified surface with an acid for a second predetermined pulse time to form a second modified surface; and

c) contacting the second modified surface with a reducing agent for a third predetermined pulse time to form a metal layer. M is such that the compound having formula 1 has a vapor pressure of at least 0.01 Torr at temperatures up to 300° C. The pKa of the conjugate acid to L is larger than the pKa of the acid used in step b).

In another embodiment, a method of forming a metal film on a substrate is provided. The method includes a deposition cycle including:

a) contacting a substrate with a vapor of a metal-containing compound described by formula 1 for a first predetermined pulse time to form a first modified surface:

MLₙ (1)

wherein:
n is 1 to 8;
M is a transition metal;
L is a ligand;

b) contacting the first modified surface with an acid for a second predetermined pulse time to form a second modified surface, the pKa of the conjugate acid to L is larger than the pKa of the acid used in this step; and

c) contacting the second modified surface with a reducing agent for a third predetermined pulse time to form a metal layer, the deposition cycle being repeated a plurality of times to form a metal film having a thickness from about 5 nanometers to about 300 nanometers.

### BRIEF DESCRIPTION OF THE DRAWINGS

FIG. 1 is a schematic illustration of an atomic layer deposition system;

FIG. 2 provides examples of suitable ligands for a metal-containing ALD precursor;

FIG. 3 provides examples of suitable ligands for a metal-containing ALD precursor;

FIG. 4 provides examples of acids that are useful in an embodiment of an ALD process;

FIG. 5 provides a plot of growth rate as a function of Cu(dmap)₂ pulse length;

FIG. 6 provides a plot of growth rate as a function of deposition temperature; and

FIG. 7 provides a plot showing the dependence of the film thickness on the number of deposition cycles.

### DESCRIPTION OF THE INVENTION

Reference will now be made in detail to presently preferred compositions, embodiments and methods of the present invention, which constitute the best modes of practicing the invention presently known to the inventors. The Figures are not necessarily to scale. However, it is to be understood that the disclosed embodiments are merely exemplary of the invention that may be embodied in various and alternative forms. Therefore, specific details disclosed herein are not to be interpreted as limiting, but merely as a representative basis for any aspect of the invention and/or as a representative basis for teaching one skilled in the art to variously employ the present invention.

Except in the examples, or where otherwise expressly indicated, all numerical quantities in this description indicating amounts of material or conditions of reaction and/or use are to be understood as modified by the word “about” in describing the broadest scope of the invention. Practice within the numerical limits stated is generally preferred. Also, unless expressly stated to the contrary: percent, “parts of,” and ratio values are by weight; the description of a group or class of materials as suitable or preferred for a given purpose in connection with the invention implies that mixtures of any two or more of the members of the group or class are equally suitable or preferred; description of constituents in chemical terms refers to the constituents at the time of addition to any combination specified in the description, and does not necessarily preclude chemical interactions among the constituents of a mixture once mixed; the first definition of an acronym or other abbreviation applies to all subsequent uses herein of the same abbreviation and applies mutatis mutandis to normal grammatical variations of the initially defined abbreviation; and, unless expressly stated to the contrary, measurement of a property is determined by the same technique as previously or later referenced for the same property.

It is also to be understood that this invention is not limited to the specific embodiments and methods described below, as specific components and/or conditions may, of course, vary. Furthermore, the terminology used herein is used only for the purpose of describing particular embodiments of the present invention and is not intended to be limiting in any way.

It must also be noted that, as used in the specification and the appended claims, the singular form “a,” “an,” and “the” comprise plural referents unless the context clearly indicates otherwise. For example, reference to a component in the singular is intended to comprise a plurality of components.

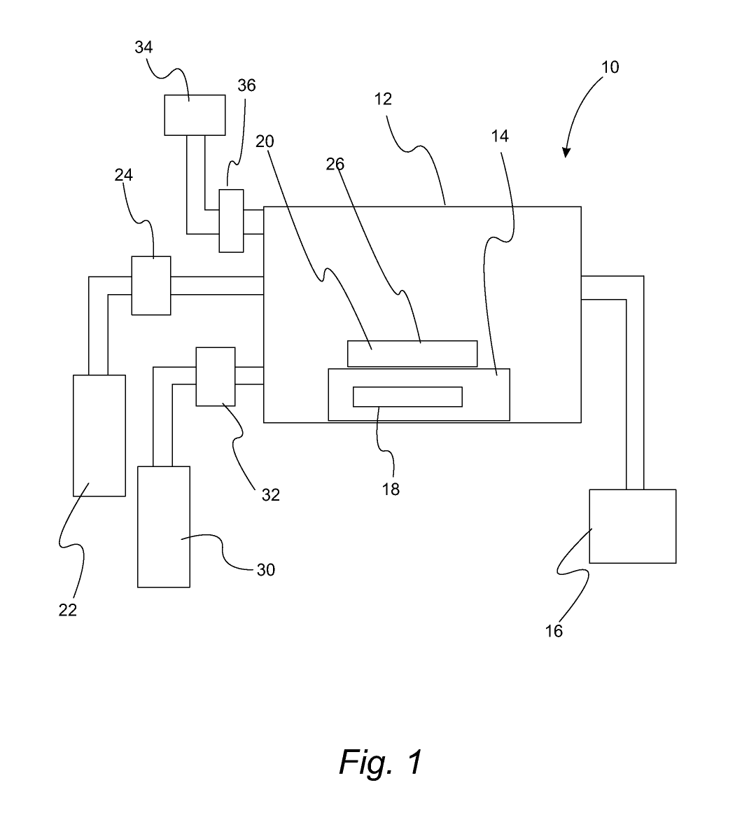

In an embodiment of the present embodiment, a method for depositing a thin film on a surface of a substrate is provided. With reference to FIG. 1, deposition system 10 includes reaction chamber 12, substrate holder 14, and vacuum pump 16. Typically, the substrate is heated via heater 18. The method has a deposition cycle that is repeated a plurality of times in order to build up the thickness of a metal film on substrate 20. During each deposition cycle, the substrate temperature is typically maintained at a temperature between 100 to 200° C. Each deposition cycle comprises contacting substrate 20 with a vapor of a metal-containing compound described by formula 1:

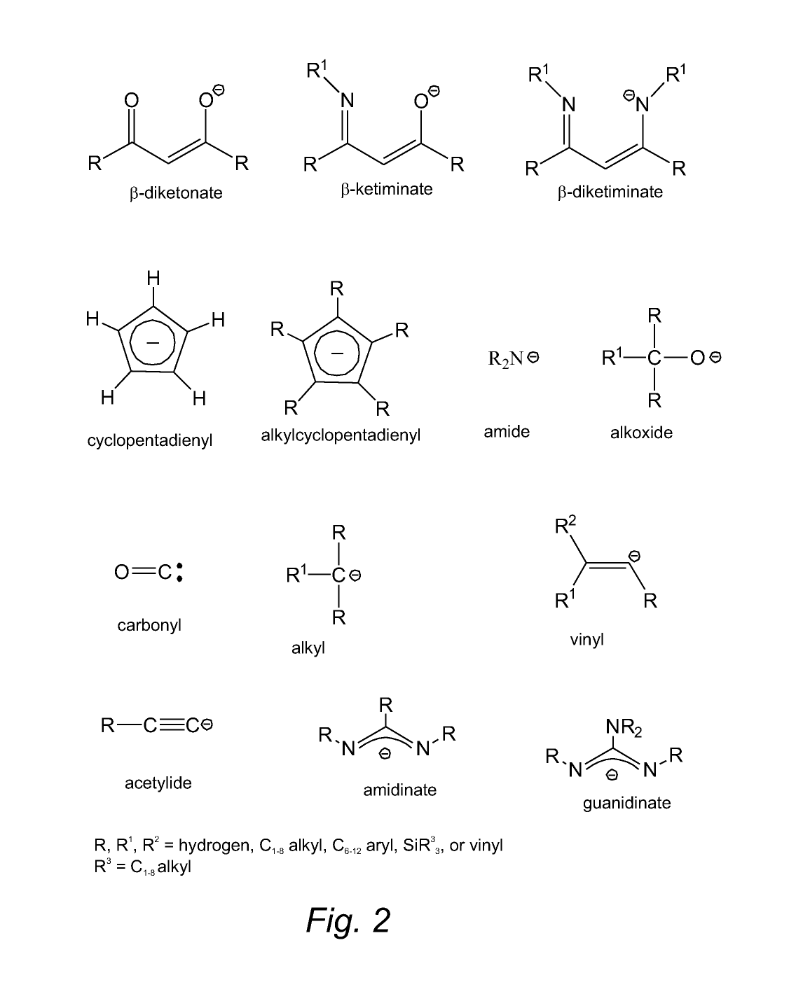

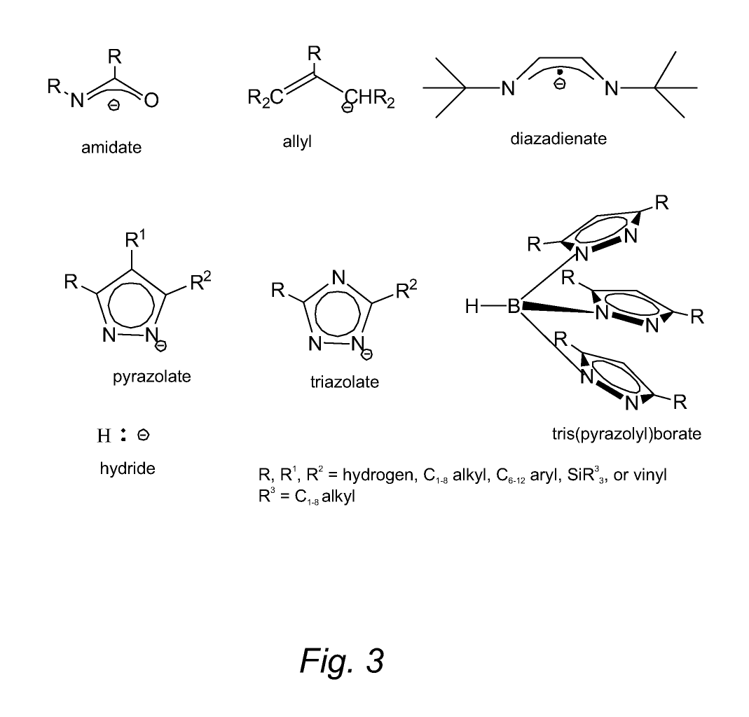

MLₙ (1)

wherein:
n is 1 to 8;
M is a transition metal;
L is a ligand; and
a variety of different ligands may be used for L. For example, L can be a two electron ligand, a multidentate ligand (e.g., a bidentate ligand), charged ligand (e.g., −1 charged), a neutral ligand, and combinations thereof. Although n gives the number of ligands, the ligands need not be the same for values of n greater than 2. Specific examples of suitable ligands are set forth in FIGS. 2 and 3. In FIGS. 2 and 3, R, R¹, R² are each independently hydrogen, C₁₋₈alkyl, C₆₋₁₂ aryl, Si(R³)₃, or vinyl and R⁴ is C₁₋₈ alkyl. In a refinement, R, R¹, R² are each independently hydrogen, C₁₋₄ alkyl, C₆₋₁₀ aryl, Si(R³)₃, or vinyl and R³ is C₁₋₈ alkyl. Examples of useful alkyl groups include, but are not limited to, methyl, ethyl, n-propyl, isopropyl, n-butyl, t-butyl, iso-butyl, sec-butyl, and the like. Examples of useful aryl groups include, but are not limited to, phenyl, tolyl, naphthyl, and the like. It should also be appreciated that R, R¹, R² may be optionally substituted with groups such as halide. A particularly useful ligand is dimethylamino-2-propoxide. In a refinement, the pKa of the conjugate acid to L is larger than the pKa of the acid used in step b). In another refinement, M is such that the compound having formula 1 has a vapor pressure of at least 0.01 ton at temperatures up to 300° C.

In a refinement of the present embodiment, M is a transition metal in the 0 to +6 oxidation state. In a further refinement, M is a transition metal in the +1 to +6 oxidation state. In still a further refinement, M is a transition metal in the +2 oxidation state. Examples of useful metals for M include, but are not limited to, silver, palladium, platinum, rhodium, iridium, cobalt, ruthenium, manganese, nickel, and copper.

Still referring to FIG. 1, the vapor is introduced from precursor source 22 into reaction chamber 12 for a first predetermined pulse time. In a variation, the compound from precursor source 22 is introduced into chamber 12 by direct liquid injection. The first predetermined pulse time should be sufficiently long that available binding sites on the substrate surface (coated with metal layers or uncoated) are saturated (i.e., metal-containing compound attached). Typically, the first predetermined pulse time is from 1 second to 20 seconds. The first predetermined pulse time is controlled via control valve 24. At least a portion of the vapor of the metal-containing compound modifies (e.g, adsorbs or reacts with) substrate surface 26 to form a first modified surface. Reaction chamber 12 is then purged with an inert gas for a first purge time. The first purge time is sufficient to remove the metal-containing compound from reaction chamber 12 and is typically from 0.5 seconds to 2 minutes.

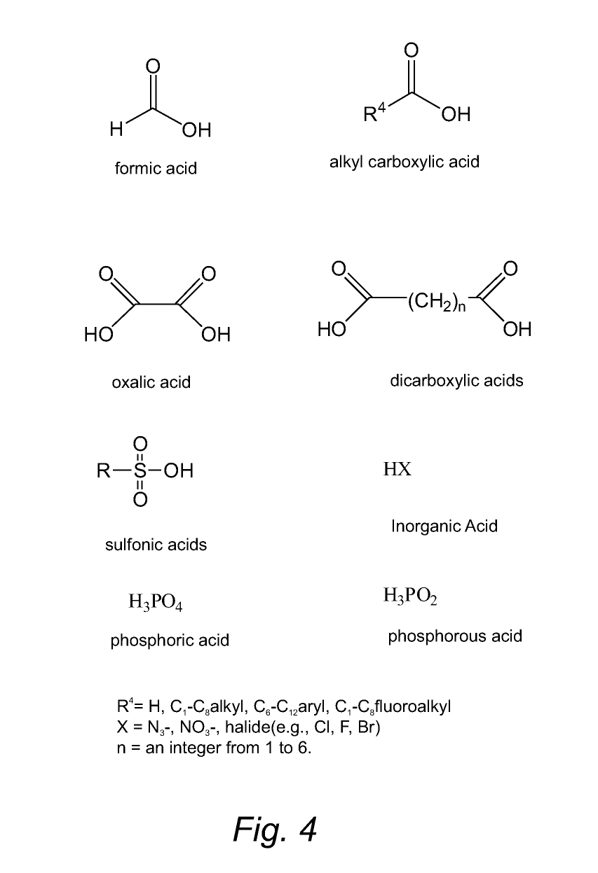

In the next reaction step of the deposition cycle, an acid such as formic acid is then introduced from acid source 30 into reaction chamber 12 for a second predetermined pulse time. Examples of other suitable acids are provided in FIG. 4. In FIG. 4, R⁴ is H (i.e., hydride), C₁₋₈ alkyl, C₆₋₁₂ aryl, or C₁₋₈ fluoroalkyl, X is N₃⁻, NO₃⁻, halide(e.g., Cl, F, Br), and n is an integer from 1 to 6. In a refinement, R⁴ is hydride, C₁₋₄ alkyl, C₆₋₁₀ aryl, or C₁₋₄ fluoroalkyl, X is N₃⁻, NO₃⁻, halide (e.g., Cl, F, Br), and n is an integer from 1 to 6. Examples of useful alkyl groups include, but are not limited to, methyl, ethyl, n-propyl, isopropyl, n-butyl, t-butyl, iso-butyl, sec-butyl, and the like. Examples of useful aryl groups include, but are not limited to, phenyl, tolyl, naphthyl, and the like. It should also be appreciated that R, R¹, R² may be optionally substituted with groups such as halide. The second predetermined pulse time should be sufficiently long that available binding sites on the first modified substrate surface are saturated and a second modified surface is formed. Typically, the second predetermined pulse time is from 0.1 second to 20 seconds. The second predetermined pulse time is controlled via control valve 32. Reaction chamber 12 is then purged with an inert gas for a second purge time (typically, 0.5 seconds to 2 minutes as set forth above).

In the final reaction step of the deposition cycle, a reducing agent is then introduced from reductant source 34 into reaction chamber 12 for a third predetermined time. Examples of suitable reducing agents include, but are not limited to, hydrazine, hydrazine hydrate, alkyl hydrazines, 1,1-dialkylhydrazines, 1,2-dialkylhydrazines, H₂, H₂ plasma, ammonia, ammonia plasma, silanes, disilanes, trisilanes, germanes, diborane, formalin, amine borane, dialkyl zinc, alkyl aluminum, alkyl gallium, alkyl indium complexes, and other plasma-based gases, and combinations thereof. The third predetermined pulse time should be sufficiently long that available binding sites on the second modified substrate surface are saturated with a metal layer being formed thereon. Typically, the third predetermined pulse time is from 0.1 second to 20 seconds. Reaction chamber 12 is then purged with an inert gas for a third purge time (typically, 0.5 seconds to 2 minutes as set forth above).

It should be appreciated that pulse times and purge times also depend on the properties of the chemical precursors and the geometric shape of the substrates. Thin film growth on flat substrates uses short pulse and purge times, but pulse and purge times in ALD growth on 3-dimensional substrates can be very long. Therefore, in one refinement, pulse times and purge times are each independently from about 0.0001 to 200 seconds. In another refinement, pulse and purge times are each independently from about 0.1 to about 10 seconds.

The desired metal film thickness depends on the number of deposition cycles. For example, for a copper film deposited from Cu(dmap)₂ (dmap=dimethylamino-2-propoxide), 1000 cycles typically results in a thickness of about 500 angstroms. Therefore, in a refinement, the deposition cycle is repeated a plurality of times to form a predetermined thickness of the metal film. In a further refinement, the deposition cycle is repeated a plurality of times to form a metal film having a thickness from about 5 nanometers to about 200 nanometers. In still another refinement, the deposition cycle is repeated a plurality of times to form a metal film having a thickness from about 5 nanometers to about 300 nanometers. In yet another refinement, the deposition cycle is repeated a plurality of times to form a metal film having a thickness from about 5 nanometers to about 100 nanometers.

During film formation by the method of the present embodiment, the substrate temperature will be at a temperature suitable to the properties of the chemical precursor(s) and film to be formed. In a refinement of the method, the substrate is set to a temperature from about 0 to 1000° C. In another refinement of the method, the substrate has a temperature from about 50 to 450° C. In another refinement of the method, the substrate has a temperature from about 100 to 250° C. In still another refinement of the method, the substrate has a temperature from about 150 to 400° C. In another refinement of the method, the substrate has a temperature from about 200 to 300° C.

Similarly, the pressure during film formation is set at a value suitable to the properties of the chemical precursors and film to be formed. In one refinement, the pressure is from about 10⁻⁶ Torr to about 760 Torr. In another refinement, the pressure is from about 0.1 millitorr to about 10 Torr. In still another refinement, the pressure is from about 1 to about 100 millitorr. In yet another refinement, the pressure is from about 1 to 20 millitorr.

The following examples illustrate the various embodiments of the present invention. Those skilled in the art will recognize many variations that are within the spirit of the present invention and scope of the claims.

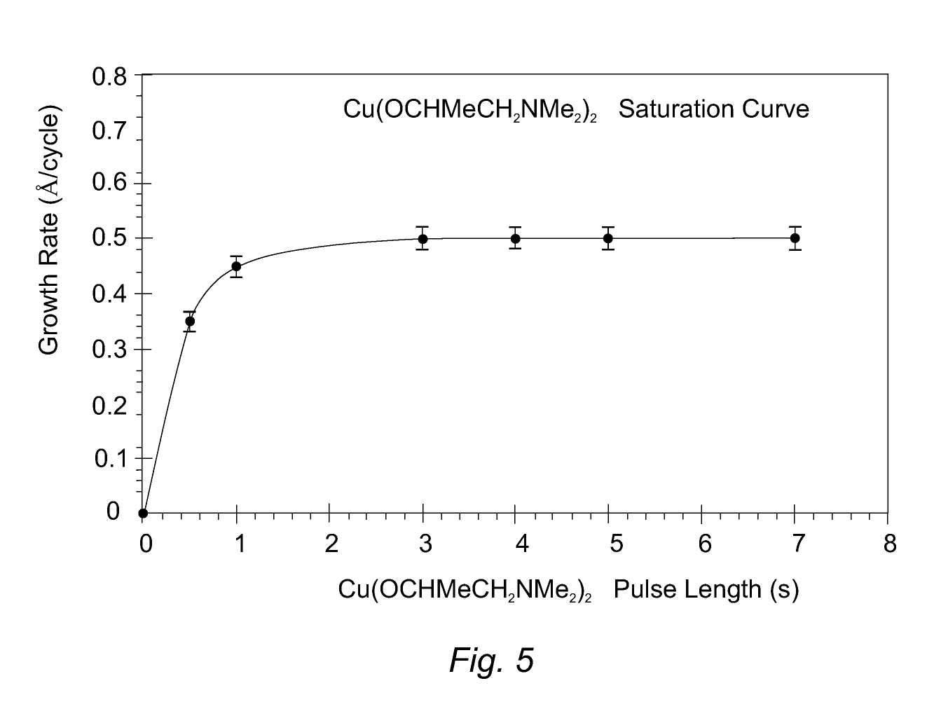

Growth of Cu films by ALD was carried out using Cu(dmap)₂ (dmap=dimethylamino-2-propoxide), formic acid, and anhydrous hydrazine. To assess the growth behavior, precursor pulse lengths, substrate temperatures, and the number of cycles were varied. The growth rate was investigated as a function of Cu(dmap)₂ pulse length at 120° C. The number of deposition cycles, length of Cu(dmap)₂, formic acid, and anhydrous hydrazine pulses, and inert gas purge times were kept constant at 1000, 3.0 s, 0.2 s, 0.2 s, and 5.0 s, respectively. As shown in FIG. 5, Cu(dmap)₂ pulse lengths of ≧3 s afforded a constant growth rate of about 0.50 Å per cycle. A lower growth rate of 0.45 and 0.35 Å per cycle was observed at Cu(dmap)₂ pulse lengths of 1.0 and 0.5 s, respectively. A key requirement of ALD growth is that all of the available surface sites react with the gaseous precursor during each precursor pulse. Once this condition is met, a constant growth rate is observed even with excess precursor flow, provided that the precursor does not undergo thermal decomposition. Inspection of FIG. 5 indicates that self-limiting film growth occurred at Cu(dmap)₂ pulse lengths of ≧3.0 s, and shorter pulse times may lead to sub-saturative growth. For the studies herein, Cu(dmap)₂ pulses of 3.0 s were employed to ensure self-limiting growth. Similar plots of growth rate versus formic acid pulse length and growth rate versus anhydrous hydrazine pulse length showed saturative behavior with ≧0.2 s pulses for both reagents. These experiments demonstrate that the film growth at 120° C. proceeds by a self-limiting ALD mechanism. Under optimized deposition conditions (3.0 s Cu(dmap)₂, 5.0 s purge, 0.2 s formic acid, 5.0 s purge 0.2 s anhydrous hydrazine, 5.0 s purge), a 1000 cycle deposition required about 5.0 h on a commercially available ALD reactor.

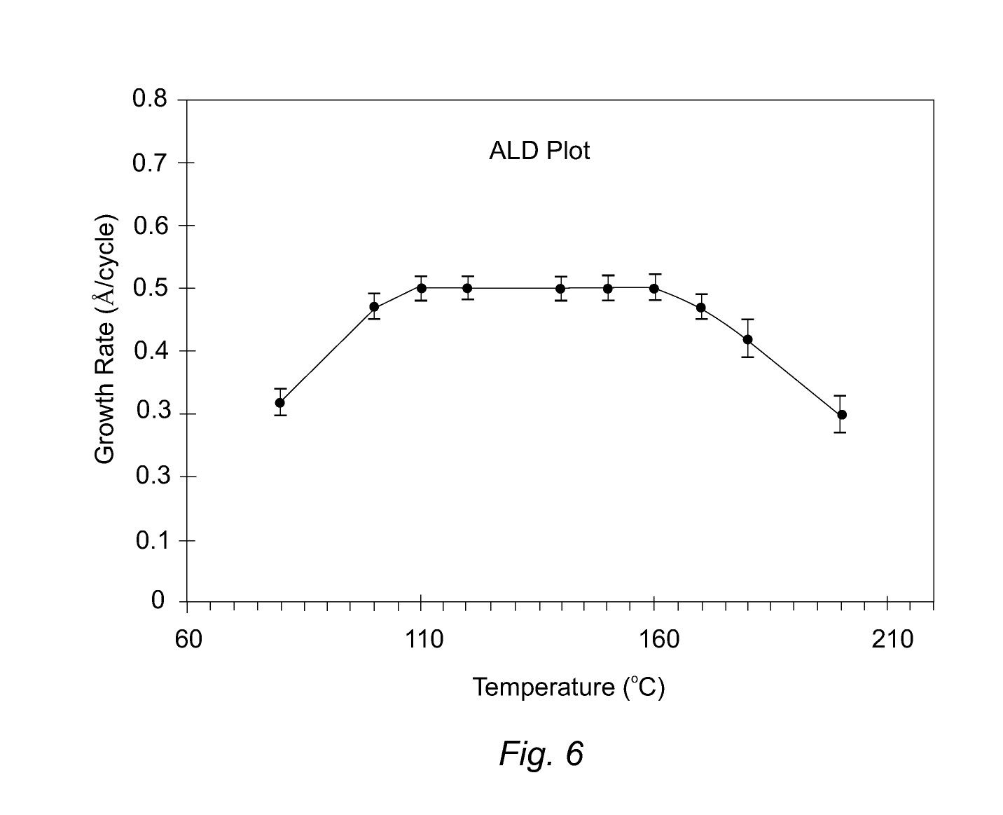

The growth rate as a function of deposition temperature was also investigated (FIG. 6). An ALD window between 110 and 160° C. is observed. The conditions in these depositions consisted of pulse lengths of 3.0 s, 0.2 s, and 0.2 s for Cu(dmap)₂, formic acid, and hydrazine, respectively, purge lengths of 5.0 s between pulses, and 1000 deposition cycles. A constant growth rate of 0.47-0.50 Å/cycle was observed between 100 and 170° C. (the ALD window). Lower growth rates occurred at 80, 180, and 200° C.

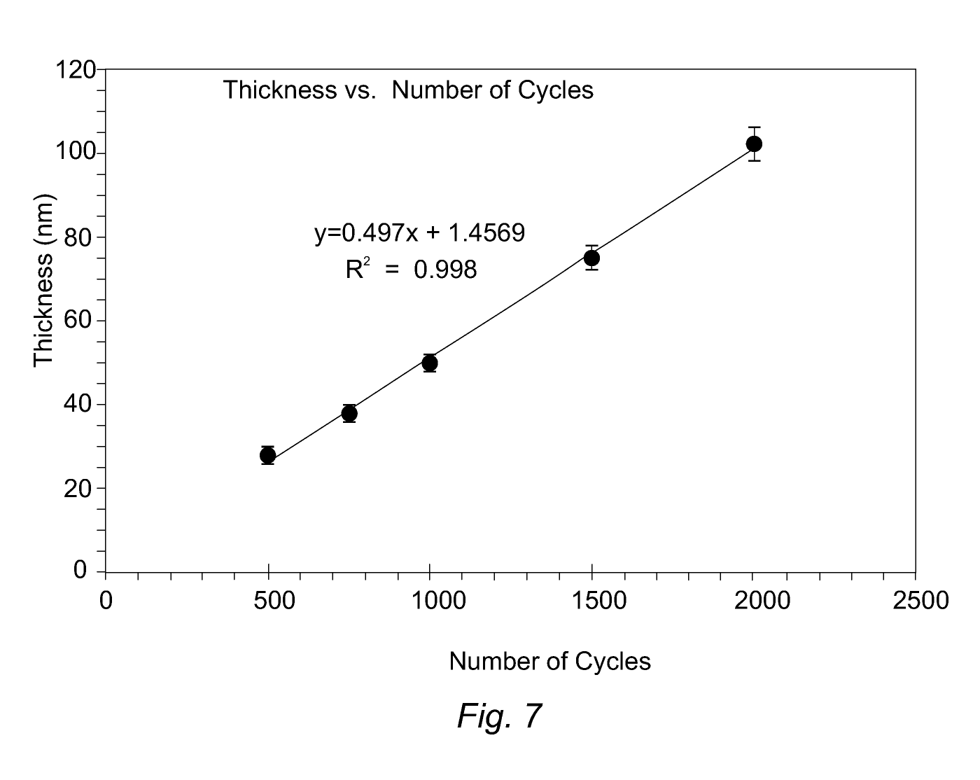

The dependence of the film thickness on the number of deposition cycles was investigated next (FIG. 7). In these experiments, the pulse lengths of Cu(dmap)₂, formic acid, and hydrazine were 3.0 s, 0.2 s, and 0.2 s, respectively, with purge lengths of 5.0 s between pulses. The deposition temperature was 120° C. The film thicknesses varied linearly with the number of cycles and the slope of the line (0.50 Å/cycle) equaled the saturative growth rate established in FIG. 5. The line of best fit shows a y-intercept of 1.46 nm, which is within experimental error of zero and suggests efficient nucleation.

Time of flight-elastic recoil detection analysis (TOF-ERDA) was performed on 45-50 nm thick films grown at 100, 120, 140, 160, and 180° C. to probe the elemental compositions (Table 1). The atomic compositions of the films range from 95.9-98.8% copper, 0.1-1.2% carbon, 0.5-1.0% oxygen, <0.4% nitrogen, and ≦2.0% hydrogen. In general, the films had the highest purity at 100° C. and the lowest purity at 180° C. Growth at the latter temperature may include some precursor self-decomposition, however, the uncertainties in the compositions preclude more definitive conclusions. Simulations demonstrate that the majority of the impurities reside at the film surface and at the interface between copper and the silicon substrate. The carbon, oxygen, and hydrogen impurities may arise from post-deposition exposure to ambient atmosphere, or from traces of formate that remain in the film.

TABLE 1
Percentages of C, O, N, and H in copper
films obtained by TOF-ERDA.

| Temp ° C. | % C | % O | % N | % H |
|---|---|---|---|---|
| 100 | 0.1 ± 0.1 | 0.5 ± 0.2 | ≦0.1 | <0.5 |
| 120 | 1.0 ± 0.3 | 0.5 ± 0.2 | 0.2 ± 0.1 | 1.2 ± 0.5 |
| 140 | 0.5 ± 0.2 | 1.0 ± 0.3 | 0.15 ± 0.1 | 2.0 ± 0.5 |
| 160 | 0.9 ± 0.3 | 0.8 ± 0.3 | 0.15 ± 0.1 | 0.9 ± 0.4 |
| 180 | 1.2 ± 0.4 | 1.0 ± 0.3 | 0.4 ± 0.2 | 1.5 ± 0.5 |

X-ray photoelectron spectroscopy (XPS) was performed on 50 nm thick copper films deposited at 140° C. to assess the composition of the films. The surface of the as-deposited film showed the expected ionizations arising from metallic copper, as well as small ionizations from oxygen and carbon. Nitrogen concentrations were at or below the detection limit (<1%). After argon ion sputtering, a constant composition of 95.1 at % copper, 1.2 at % carbon, 3.1 at % oxygen, and <1 at % nitrogen was observed. The Cu2p ½ and Cu2p 3/2 ionizations appeared at 952.2 and 932.4 eV, which are exact matches for copper metal.

Powder X-ray diffraction experiments were performed on a 45 nm thick film deposited at 100° C. and on 50 nm thick films that were grown at 120, 140, 160, and 180° C. All of the as-deposited films were crystalline, and showed reflections arising from the (111), (200), and (220) planes of copper metal (JCPDS file number 04-0836). The AFM image of a 50 nm thick film grown at 120° C. had an rms surface roughness of 3.5 nm. The SEM images of a film deposited under the same conditions showed no cracks or pinholes and a very uniform surface. The resistivities of 45-50 nm thick copper films deposited at 100, 120, and 140° C. ranged from 9.6 to 16.4 μΩ cm at 20° C., compared to the bulk resistivity of copper of 1.72 μΩ cm at 20° C. For comparison, sputtered 40-50 nm thick copper films on SiO₂ substrates had resistivities of 6-8 μΩ cm. Hence, our resistivity values indicate high purity copper metal. Films grown at all temperatures passed the Scotch Tape test, demonstrating good adhesion.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A method of forming a metal film on a substrate, the method comprising a deposition cycle including:
a) contacting a substrate with a vapor of a metal-containing compound described by formula 1 for a first predetermined pulse time to form a first modified surface:
MLₙ (1)
wherein:
n is 1 to 8;
M is a transition metal;
L is a ligand;
b) contacting the first modified surface with an acid for a second predetermined pulse time to form a second modified surface; and
c) contacting the second modified surface with a reducing agent for a third predetermined pulse time to form a metal layer.

2. The method of claim 1 wherein M is a transition metal in the +2 oxidation state.

3. The method of claim 1 wherein M is silver, palladium, platinum, rhodium, iridium, cobalt, ruthenium, manganese, nickel, or copper.

4. The method of claim 1 wherein M is copper.

5. The method of claim 1 wherein the acid is formic acid.

6. The method of claim 1 wherein the acid comprises a component selected from the group consisting of: 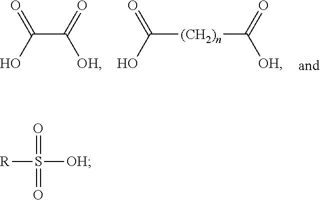
R is hydrogen, C₁₋₄ alkyl, C₆₋₁₂ aryl, Si(R³)₃, or vinyl; R³ is C₁₋₈ alkyl; and n is an integer from 1 to 6.

7. The method of claim 1 wherein the pKa of the conjugate acid to L is larger than the pKa of the acid used in step b).

8. The method of claim 1 wherein the acid comprises a component selected from the group consisting of: HX, H₃PO₄, and H₃PO_{2;} and X is N₃⁻, NO₃⁻, and halide.

9. The method of claim 1 wherein the reducing agent is selected from the group consisting of hydrazine, hydrazine hydrate, alkyl hydrazines, 1,1-dialkylhydrazines, 1,2-dialkylhydrazines, H₂, H₂ plasma, ammonia, ammonia plasma, silanes, disilanes, trisilanes, germanes, diborane, formalin, amine borane, dialkyl zinc, alkyl aluminum, alkyl gallium, alkyl indium complexes, and other plasma-based gases, and combinations thereof.

10. The method of claim 1 wherein each L independently comprises a component selected from the group consisting of a two electron ligand, a multidentate ligand, charged ligand (e.g., −1 charged), a neutral ligand, and combinations thereof.

11. The method of claim 1 wherein two L ligands are combined together as part of a bidentate ligand.

12. The method of claim 11 wherein the bidentate ligand is dimethylamino-2-propoxide.

13. The method of claim 1 wherein L is selected from the group consisting of: 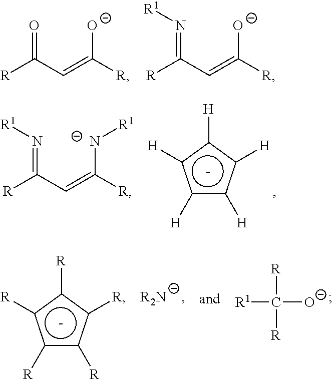
R, R¹, R² are each independently hydrogen, C₁₋₄ alkyl, C₆₋₁₂ aryl, Si(R³)₃, or vinyl; and R³ is C₁₋₈ alkyl.

14. The method of claim 1 wherein L is selected from the group consisting of: 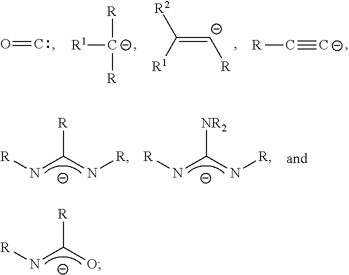
R, R¹, R² are each independently hydrogen, C₁₋₄ alkyl, C₆₋₁₂ aryl, Si(R³)₃, or vinyl; and R³ is C₁₋₈ alkyl.

15. The method of claim 1 wherein L is selected from the group consisting of: 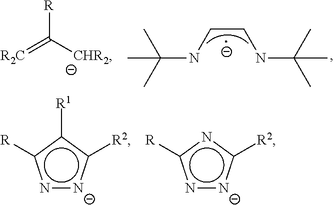
and H: ⊖; R, R¹, R² are each independently hydrogen, C₁₋₄ alkyl, C₆₋₁₂ aryl, Si(R³)₃, or vinyl; and R³ is C₁₋₈ alkyl.

16. The method of claim 1 wherein L is: 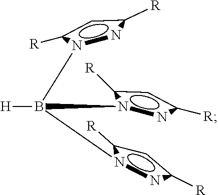
R is hydrogen, C₁₋₄ alkyl, C₆₋₁₂ aryl, Si(R³)₃, or vinyl; and R³ is C₁₋₈ alkyl.

17. The method of claim 1 wherein the deposition cycle is repeated a plurality of times to form a predetermined thickness of the metal film.

18. The method of claim 1 wherein the deposition cycle is repeated a plurality of times to form a metal film having a thickness from about 5 nanometers to about 300 nanometers.

19. A method of forming a metal film on a substrate, the method comprising a deposition cycle including:
a) contacting a substrate with a vapor of a metal-containing compound described by formula 1 for a first predetermined pulse time to form a first modified surface:
MLₙ (1)
wherein:
n is 1 to 8;
M is a transition metal;
L is a ligand;
b) contacting the first modified surface with an acid for a second predetermined pulse time to form a second modified surface, the pKa of the conjugate acid to L is larger than the pKa of the acid used in this step; and
c) contacting the second modified surface with a reducing agent for a third predetermined pulse time to form a metal layer, the deposition cycle being repeated a plurality of times to form a metal film having a thickness from about 5 nanometers to about 300 nanometers.

20. The method of claim 19 wherein L is selected from the group consisting of: dimethylamino-2-propoxide, 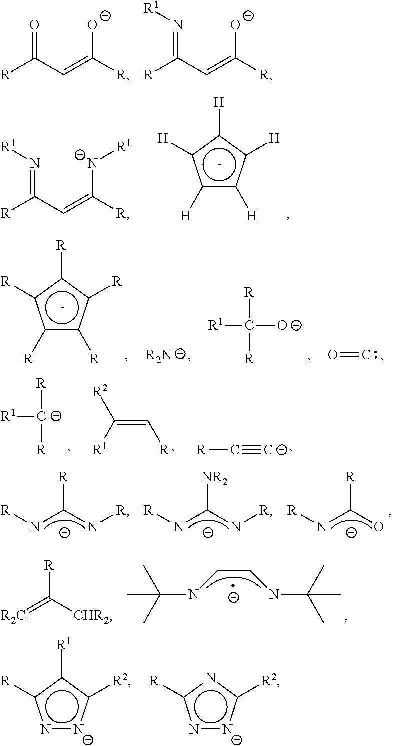
hydride, and 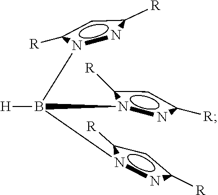
R, R¹, R² are each independently hydrogen, C₁₋₄ alkyl, C₆₋₁₂aryl, Si(R³)₃, or vinyl; and R³ is C₁₋₈ alkyl;
the acid in step b) is selected from the group consisting of: formic acid, 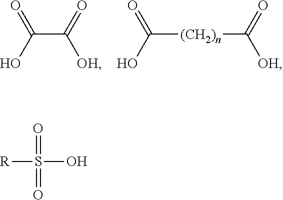
HX, H₃PO₄, and H₃PO₂;
X is N₃⁻, NO₃⁻, and halide; R is hydrogen, C₁₋₄ alkyl, C₆₋₁₂ aryl, Si(R³)₃, or vinyl; R³ is C₁₋₈ alkyl. and n is an integer from 1 to 6; and
the reducing agent is selected from the group consisting of hydrazine, hydrazine hydrate, alkyl hydrazines, 1,1-dialkylhydrazines, 1,2-dialkylhydrazines, H₂, H₂ plasma, ammonia, ammonia plasma, silanes, disilanes, trisilanes, germanes, diborane, formalin, amine borane, dialkyl zinc, alkyl aluminum, alkyl gallium, alkyl indium complexes, and other plasma-based gases, and combinations thereof.
